(19) United States
(12) Patent Application Publication
(10) Pub. No.: US 2010/0055816 A1
(43) Pub. Date: Mar. 4, 2010

(54) Light Emitting Device Manufacturing Apparatus and Method

(75) Inventors: Toshihisa Nozawa, Hyogo (JP); Yasushi Yagi, Hyogo (JP)

Correspondence Address: IPUSA, P.L.L.C, 1054 31ST STREET, N.W., Suite 400, Washington, DC, 20007, US

(73) Assignee: TOKYO ELECTRON LIMITED, TOKYO (JP)

(21) Appl. No.: 12/303,568

(22) PCT Filed: Jun. 7, 2007
(86) PCT No.: PCT/JP2007/061585

§ 371 Date: Oct. 19, 2009

(30) Foreign Application Priority Data
Jun. 7, 2006 (JP) 2006-158724

(51) Int. Cl. H01L 51/56; C23C 16/458; C23C 14/34; C23F 1/08

(52) U.S. Cl. 438/29; 118/728; 204/298.12; 156/345.31; 438/99; 257/E51.022

(57) ABSTRACT

A disclosed light-emitting-device manufacturing apparatus for manufacturing a light emitting device by forming, on an in-process substrate, an organic layer including an emitting layer includes multiple processing chambers to which the in-process substrate is sequentially transferred to be subjected to multiple substrate processing steps; and multiple substrate transfer chambers, each of which is connected to a different one of the processing chambers. A substrate holding container configured to contain the in-process substrate is sequentially connected to the substrate transfer chambers in order so that the in-process substrate is sequentially transferred to the processing chambers to be subjected to the substrate processing steps.

### TECHNICAL FIELD

The present invention relates to an apparatus and a method for manufacturing a light emitting device that includes an organic emitting layer.

### BACKGROUND ART

In place of CRTs (cathode ray tubes) which have been used conventionally, flat-screen devices allowing a reduction in the thickness of the screens have been increasingly put into practical use in recent years For example, organic electroluminescence devices (organic EL devices) have characteristics of self light emission, fast response and the like, and therefore have attracted attention as next generation display devices. Organic EL devices are used not only as display devices but also as surface emitting devices.

An organic EL device has a structure in which an organic layer including an organic EL layer (emitting layer) is sandwiched between a positive electrode (anode), and a negative electrode (cathode). The emitting layer is designed to emit light when holes and electrons are injected into the emitting layer from the positive electrode and the negative electrode, respectively, and then recombine.

In the organic layer, a hole transport layer or an electron transport layer may be included, if needed, between the emitting layer and the positive electrode or between the emitting layer and the negative electrode in order to improve luminous efficiency.

To form the above-described light emitting device, the following method has been commonly used. First, an organic layer is formed by vapor deposition on a substrate on which the positive electrode made of ITO (indium tin oxide) has been patterned. Vapor deposition is a process for forming a thin layer by depositing, for example, an evaporated or sublimated material on an in-process substrate. Subsequently, Al (aluminum) to function as a negative electrode is formed on the organic layer by vapor deposition or the like.

In the above-described manner, for example, a light emitting device having an organic layer sandwiched between positive and negative electrodes can be formed (for example, see Patent Document 1).

In the case of manufacturing the above light emitting device, a so-called cluster manufacturing apparatus may be used. A cluster manufacturing apparatus has a structure in which multiple processing chambers (e.g. layer forming chambers) are connected to a transfer chamber having a polygonal shape in a planar view.

### [Patent Document 1] Japanese Laid-open Patent Application Publication No. 2004-225058

### DISCLOSURE OF THE INVENTION

### Problems to be Solved by the Invention

However, there are concerns that the organic layer including an emitting layer tends to easily change its properties due to oxygen and water in the ambient atmosphere, which results in a reduction in the quality of the light emitting device. Accordingly, it is often the case in conventional techniques that the organic layer of the light emitting device is covered by a protective film made of an inorganic material (silicon oxide film or silicon oxynitride film) that exhibits comparatively stable properties in the atmosphere.

However, the manufacturing process of the light emitting device includes a stage when the organic layer is being uncovered. Accordingly, if the organic layer is exposed to the atmosphere due to, for example, failure or maintenance of the manufacturing apparatus, it is sometimes the case that the light emitting device yield decreases, leading to production decline. In addition, as for conventional cluster apparatuses, there are limitations in handling failure situations and maintenance of the manufacturing apparatuses due to the necessity of preventing the organic layer from being exposed to the atmosphere, thereby posing a problem for the improvement of the light emitting device production.

### Means for Solving Problems

The present invention aims at providing a new and useful apparatus and method for manufacturing a light emitting device, which are free from the foregoing problems associated with the conventional devices and techniques.

More specifically, the present invention provides an apparatus and method for manufacturing a light emitting device with good productivity.

One aspect of the present invention may be to provide a light-emitting-device manufacturing apparatus for manufacturing a light emitting device by forming, on an in-process substrate, an organic layer including an emitting layer. The light-emitting-device manufacturing apparatus includes multiple processing chambers to which the in-process substrate is sequentially transferred to be subjected to multiple substrate processing steps; and multiple substrate transfer chambers, each of which is connected to a different one of the processing chambers.

A substrate holding container configured to contain the in-process substrate is sequentially connected to the substrate transfer chambers in order that the in-process substrate is sequentially transferred to the processing chambers to be subjected to the substrate processing steps.

Another aspect of the present invention may be to provide a light-emitting-device manufacturing method for manufacturing a light emitting device by performing multiple substrate processing steps in multiple processing chambers to thereby form, on an in-process substrate, an organic layer including an emitting layer. A substrate holding container which contains the in-process substrate therein is sequentially connected to multiple substrate transfer chambers, each of which is connected to a different one of the processing chambers, in order that the in-process substrate is sequentially transferred to the process chambers to be subjected to the substrate processing steps.

### EFFECT OF THE INVENTION

According to the present invention, it is possible to provide an apparatus and method for manufacturing a light emitting device with good productivity.

### BRIEF DESCRIPTION OF DRAWINGS

FIG. 1 shows a light-emitting-device manufacturing apparatus according to a first embodiment;

FIG. 2 is a cross-sectional view of the manufacturing apparatus of FIG. 1;

FIG. 3A shows a light-emitting-device manufacturing method (step 1) according to the first embodiment;

FIG. 3B shows the light-emitting-device manufacturing method (step 2) according to the first embodiment;

FIG. 3C shows the light-emitting-device manufacturing method (step 3) according to the first embodiment;

FIG. 3D shows the light-emitting-device manufacturing method (step 4) according to the first embodiment;

FIG. 3E shows the light-emitting-device manufacturing method (step 5) according to the first embodiment;

FIG. 3F shows the light-emitting-device manufacturing method (step 6) according to the first embodiment;

FIG. 4 shows a processing chamber (e.g. 1) used in the manufacturing apparatus of FIG. 1;

FIG. 5 shows another processing chamber (e.g. 2) used in the manufacturing apparatus of FIG. 1;

FIG. 6 shows another processing chamber (e.g. 3) used in the manufacturing apparatus of FIG. 1;

FIG. 7 shows another processing chamber (e.g. 4) used in the manufacturing apparatus of FIG. 1; and

FIG. 8 shows a modification of the manufacturing apparatus of FIG. 1.

### EXPLANATION OF REFERENCE SYMBOLS

100, 200 light-emitting-device manufacturing apparatus
CL1, EL1 SP1, ET1, SP2, CVD1 processing chamber
T1, T2, T3, T4, T5, T6 substrate transfer chamber
B1 substrate holding container
W in-process substrate
BA1 BA2 holding container station
100A control unit
11 substrate
12 positive electrode
13 draw-out electrode
14 organic layer
15 negative electrode
16 protective layer

### BEST MODE FOR CARRYING OUT THE INVENTION

A semiconductor apparatus and a manufacturing method of the same according to embodiments of the present invention are described next with reference to the drawings.

A light-emitting-device manufacturing apparatus according to one embodiment of the present invention manufactures a light emitting device by forming on an in-process substrate an organic layer including an emitting layer. The manufacturing apparatus includes multiple processing chambers to which the in-process substrate is sequentially transferred to be subjected to multiple substrate processing steps; and multiple substrate transfer chambers, each of which is connected to a different one of the processing chambers.

In addition, the light-emitting-device manufacturing apparatus according to one embodiment of the present invention is characterized in that a substrate holding container configured to contain the in-process substrate is sequentially connected to the substrate transfer chambers. In this manners the in-process substrate is sequentially transferred to the multiple processing chambers to be subjected to the substrate processing steps.

For example, in the case of a conventional cluster apparatus for manufacturing a light emitting device, there are concerns that the organic layer is exposed to the atmosphere due to failure or maintenance of the manufacturing apparatus, which could lead to degradation of the quality of the light emitting device. In addition, there are limitations in handling failure situations and maintenance of the manufacturing apparatuses due to the necessity of preventing the organic layer from being exposed to the atmosphere, thereby posing a problem for the improvement of the light emitting device production.

On the other hand, in the manufacturing apparatus according to one embodiment of the present invention, an in-process substrate on which an organic layer is formed is transferred while protected (hermetically contained) in a substrate holding container, and the substrate holding container is sequentially connected to the substrate transfer chambers T1-T6. Accordingly, there is less concern that the organic layer may be exposed to the atmosphere, and it is possible to manufacture high-quality light emitting devices with good productivity.

Since the in-process substrate on which the organic layer is formed is transferred while hermetically contained in the substrate holding container, maintenance and failure repairs of the processing chambers can be handled readily, which results in an improvement in the productivity of the manufacturing apparatus.

Since there is a smaller risk of the in-process substrate being exposed to the atmosphere, flexibility in the structures, transfer path and maintenance methods of the processing chambers dramatically improves, resulting in an improvement in the productivity of the manufacturing apparatus.

With reference to the drawings, the following describes a structural example of the above-described light-emitting-device manufacturing apparatus as well as an example of a light-emitting-device manufacturing method using the manufacturing apparatus.

### 1. First Embodiment

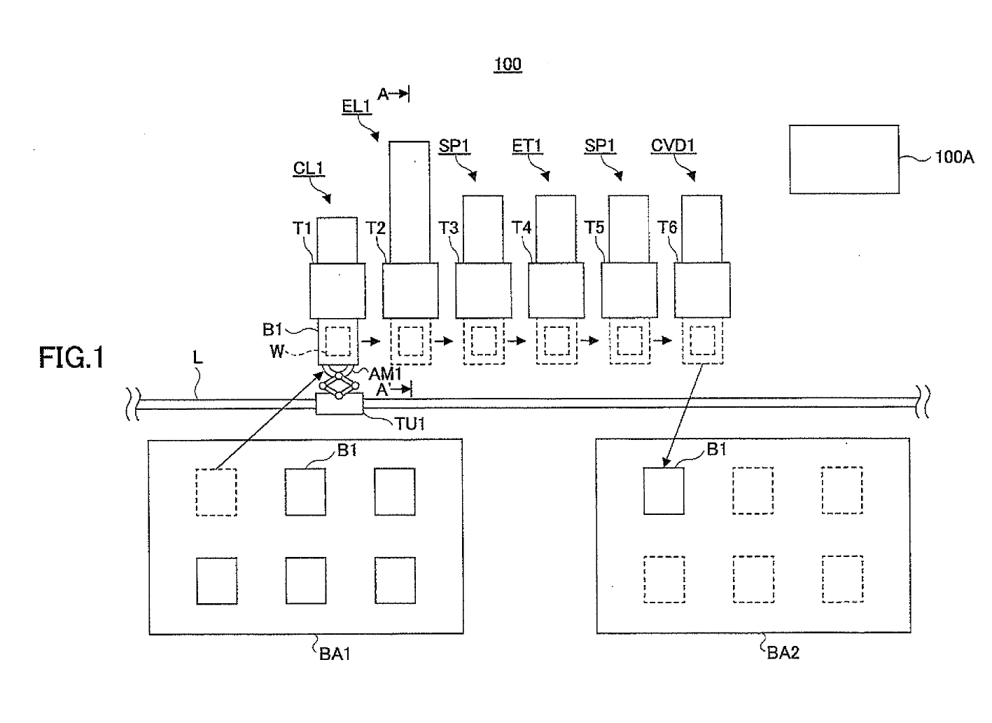

FIG. 1 is a schematic plan view of a light-emitting-device manufacturing apparatus 100 according to the first embodiment of the present invention. With reference to FIG. 1, the manufacturing apparatus 100 includes multiple processing chambers CL1, EL1, SP1, ET1, SP2 and CVD1, in each of which a substrate processing step is performed on an in-process substrate W. Substrate transfer chambers T1, T2, T3, T4, T5 and T6 are connected to the processing chambers CL1, EL1, SP1, ET1, SP2 and CVD1, respectively. In each of the substrate transfer chambers T1-T6, a substrate transfer unit (not shown in FIG. 1), e.g. a transfer arm, is provided so that the in-process substrate can be transferred from a substrate holding container (described below) to a processing chamber to which the substrate transfer chamber T1-T6 is connected and from the processing chamber to the substrate holding container.

In the manufacturing apparatus, the in-process substrate W is subjected to multiple substrate process steps subsequently performed in the processing chambers CL1, EL1, SP1, ET1, SP2 and CVD1. After the substrate processing steps in the processing chambers CL1, EL1, SP1, ET1, SP2 and CVD1, an organic layer which includes an emitting layer, and electrodes used for applying a voltage to the organic layer are formed on the in-process substrate, and thus, a light emitting device is manufactured.

The manufacturing apparatus 100 of the present embodiment is characterized in that a substrate holding container B1 is transferred while containing the in-process substrate W, and sequentially connected to the multiple substrate transfer chambers T1-T6.

When the substrate holding container B1 is connected to a substrate transfer chamber T1-T6, the in-process substrate W is transferred by the substrate transfer unit provided inside the substrate transfer chamber T1-T6 from the substrate holding container B1 to the corresponding processing chamber CL1, EL1, SP1, ET1, SP2 or CVD1 to which the substrate transfer chamber T1-T6 is connected.

For example, in the case of the substrate transfer chamber T1, the in-process substrate W is transferred to the processing chamber CL1 from the substrate holding container B1 when connected to the substrate transfer chamber T1; and subsequently, a substrate process step is performed on the in-process substrate W in the processing chamber CL1. After the substrate processing step in the processing chamber CL1 is finished, the in-process substrate W is transferred back to the substrate holding container B1. Then, the substrate holding container B1 containing the in-process substrate W is connected to the substrate transfer chamber T2, and similar operations take place (that is, transfer of the in-process substrate W to the processing chamber EL1, a substrate processing step in the processing chamber EL1, and transfer of the in-process substrate W back to the substrate holding container B1).

In a similar manner, the substrate holding container B1 is sequentially connected to the next adjacent substrate transfer chamber. For example, the substrate holding container B1 is first connected to the substrate transfer chamber T1, and then sequentially connected to the substrate transfer chambers T2, T3, T4, T5 and T6. When the substrate holding container B1 is connected to a substrate transfer chamber T1-T6, the in-process substrate W is transferred to a corresponding processing chamber to which the substrate transfer chamber T1-T6 is connected, and a substrate processing step is then performed. That is to say, the in-process substrate W is subjected to substrate processing steps sequentially performed in the processing chambers CL1, EL1, SP1, ET1, SP2 and CVD 1, and thus, a light emitting device is formed.

In this case, the substrate holding container B1 is transferred while held by a holding-container transfer unit TU1. The holding-container transfer unit TU1 is designed to travel parallel to and along a transfer rail L. Also, in the holding-container transfer unit TU1, a transfer arm AM1 is provided for pressing the substrate holding container BE1 against a substrate transfer chamber T1-T6 to thereby connect them together and detaching the attached substrate container B1 from the substrate transfer chamber T1-T6.

Multiple substrate holding containers B1, each containing an in-process substrate W on which a light emitting device has yet to be formed (i.e. prior to the formation of a light emitting device), are aligned in a holding container station BA1. The holding-container transfer unit TU1 picks up a substrate holding container B1 from the holding container station BA1, and transfers and then connects it to the substrate transfer chamber T1.

On the other hand, multiple substrate holding containers B1, each containing an in-process substrate W on which the light emitting device is formed by the completion of the substrate processing steps, are aligned in a holding container station BA2. The substrate holding container B1 that contains the in-process substrate W having the light emitting device (after the substrate processing step in the processing chamber CVD1) is detached from the substrate transfer chamber T6 by the holding-container transfer unit TU1, and then transferred to and placed in the holding container station BA2.

Operations of the holding-container transfer unit TU1 and the substrate transfer units (not shown) inside the transfer chambers T1-T6 as well as operations related to the substrate processing steps (manufacture of a light emitting device) in the processing chambers CL1, EL1, SP1, ET1, SP2 and CVD1 are controlled by a control unit 100A having a CPU (not shown) inside.

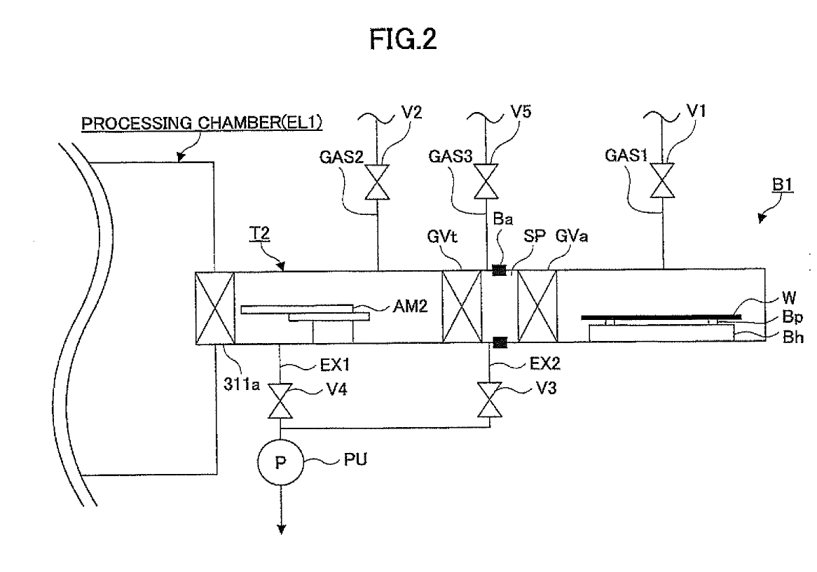

FIG. 2 is a schematic cross-sectional view along line A-A′ of FIG. 1. In FIG. 2, the same reference numerals are given to components that have been described above, and their explanations may be omitted herein. FIG. 2 shows the substrate holding container B1 connected to the substrate transfer chamber T2.

With reference to FIG. 2, the substrate holding container B1 includes a mounting platform Bh on which the in-process substrate W is placed and thrust pins Bp for supporting the in-process substrate W. Also, a gas line GAS1 to which a valve V1 is attached is connected to the substrate holding container B1. By opening the valve V1, a predetermined fill gas (e.g. an inert gas, such as Ar, or N₂ gas) can be supplied from the gas line GAS1 to the substrate holding container B1.

A gate valve GVa is provided on the substrate holding container B1, at the end connected to the substrate transfer chamber T2. By opening the gate valve GVa, the in-process substrate W can be carried out from/into the substrate holding container B1.

On the other hand, the substrate transfer chamber T2 includes a transfer unit (transfer arm) AM2 used for transferring the in-process substrate W. The transfer unit AM2 transfers the in-process substrate W from the substrate holding container B1 to the processing chamber EL1 as well as from the processing chamber EL1 to the substrate holding container B1.

A gate valve GVt is provided on the substrate transfer chamber T2, at the end facing the substrate holding container B1. Also, a gate valve 311a is provided on the substrate transfer chamber T2, at the end facing the processing chamber EL1. The gate valves GVt and 311a are opened when the in-process substrate W is transferred from the substrate holding container B1 to the processing chamber EL1 and from the processing chamber EL1 to the substrate holding container B1.

Also, a gas line GAS2 to which a valve V2 is attached is connected to the substrate transfer chamber T2. By opening the valve V2, a predetermined fill gas (e.g. an inert gas, such as Ar, or N₂ gas) can be supplied from the gas line GAS2 to the substrate transfer chamber T2. Furthermore, an exhaust line EX1 having a vacuum pump PV and a valve V4 is connected to the substrate transfer chamber T2. By opening the valve V4, the inside of the substrate transfer chamber T2 can be brought to a predetermined reduced pressure.

The substrate transfer chamber T2 is connected to the substrate holding container B1, at the end where the gate valve GVt is provided. At this point, a space SP is defined between the gate valves GVt and GVa. In addition, the substrate transfer chamber T2 and the substrate holding container B1 are connected to each other via sealing members Ba, and thus, air tightness of the inside of the substrate transfer chamber T2 and the substrate holding container B1 can be maintained.

The space SP is designed such that a predetermined fill gas (e.g. an inert gas, such as Ar, or N₂ gas) can be supplied from a gas line GAS3 to which a valve V5 is attached. The space SP can be brought to a predetermined reduced pressure by an exhaust line EX2 connected to the exhaust line EX1 and having a valve V3 attached.

The substrate processing step at the processing chamber EL1 is performed on the in-process substrate W, for example, in a manner described below. The substrate holding container B1 having the in-process substrate W on the mounting platform Bp is transferred by the holding-container transfer unit TU1, and then connected to the substrate transfer chamber T2.

The inside of the substrate transfer chamber T2 has been brought to a predetermined reduced pressure by producing a vacuum in advance using the exhaust line EX1. At this point, by opening the valve V3, the space SP is also brought to a reduced pressure.

Subsequently, the gate valves GVa and GVt are opened, and the in-process substrate W is transferred by the substrate transfer unit AM2 from the substrate holding container B1 into the substrate transfer chamber T2. After the gate valves GVt and GVa are closed, the gate valve 311a is opened. Next, the in-process substrate W is transferred by the substrate transfer unit AM2 into the processing chamber EL1, and the gate valve 311a is then closed. Subsequently, a predetermined substrate processing step (for example, the formation of an organic layer) is performed in the processing chamber EL1. After the completion of the substrate processing step, the in-process substrate W is transferred by the transfer unit AM2 back to the substrate holding container B1 via the substrate transfer chamber T2.

At this point, since a vacuum has been produced inside the substrate holding container B1 for a predetermined period of time (while the gate valves GVt and GVa are open) using the exhaust lines EX1 and EX2, the predetermined reduced pressure is maintained even when the in-process substrate W is again hermetically contained in the substrate holding container B1 after the gate valve GVa is closed. Herewith, until the substrate holding container B1 is connected to the next substrate transfer chamber, the organic layer formed on the in-process substrate W can be prevented from quality degradation due to exposure to oxygen and water in the atmosphere.

After the in-process substrate W is returned to the substrate holding container B1, the substrate holding container B1 may be filled with a predetermined fill gas supplied from the gas line GAS1. As for the fill gas, a noble gas, such as Ar, or nitrogen can be used. That is, the content inside the substrate holding container B1 is replaced with the fill gas. This allows effectively preventing the degradation of the organic layer on the in-process substrate.

For example, in the case where the atmosphere inside the substrate holding container B1 is replaced with the fill gas, the difference between the pressure inside the substrate holding container B1 and the ambient atmosphere becomes smaller compared to the case of the inside atmosphere being brought to a reduced pressure. As a result, it is less likely that air from the ambient atmosphere enters the substrate holding container B1 due to leakage, so that the quality degradation of the organic layer can be effectively prevented.

After the completion of the substrate processing step, the substrate holding container B1 containing the in-process substrate W is detached from the substrate transfer: chamber T2, and then connected to the substrate transfer chamber T3. It is preferable to supply a predetermined amount of gas to the space SP through the gas line GAS3 during the time when the substrate holding container B1 is being detached from the substrate transfer chamber T2. Thus, the substrate holding container B1 is sequentially connected to the substrate transfer chambers T1-T6 for the substrate processing steps.

The following describes, with reference to FIG. 1, an outline of the substrate processing steps performed in the respective processing chambers CL1, EL1, SP1, ET1, SP2 and CVD1 in order to manufacture the above-described light emitting device. First, multiple substrate holding containers B1, each including an in-process substrate W on which a positive electrode has been formed, are aligned in the holding container station BA1. The holding-container transfer unit TU1 picks up one substrate holding container B1 from the holding container station BA1 and then connects it to the substrate transfer chamber T1.

Subsequently, substrate processing steps take place sequentially in the processing chambers CL1, EL1, SP1, ET1, SP2 and CVD1, as explained above.

First, in the processing chamber CL1, the in-process substrate W after a positive electrode has been formed is subjected to a cleaning process. Next, in the processing chamber EL1, an organic layer including an emitting layer (organic EL layer) is formed by, for example, vapor deposition. Next, in the processing chamber SP1, a pattern of a negative electrode is formed on the organic layer by mask-sputtering. Next, in the processing chamber ET1, the organic layer is patterned by, for example, plasma etching while using the patterned negative electrode as an etching mask. This etching process removes parts of the organic layer which have to be stripped to thereby form a pattern of the organic layer.

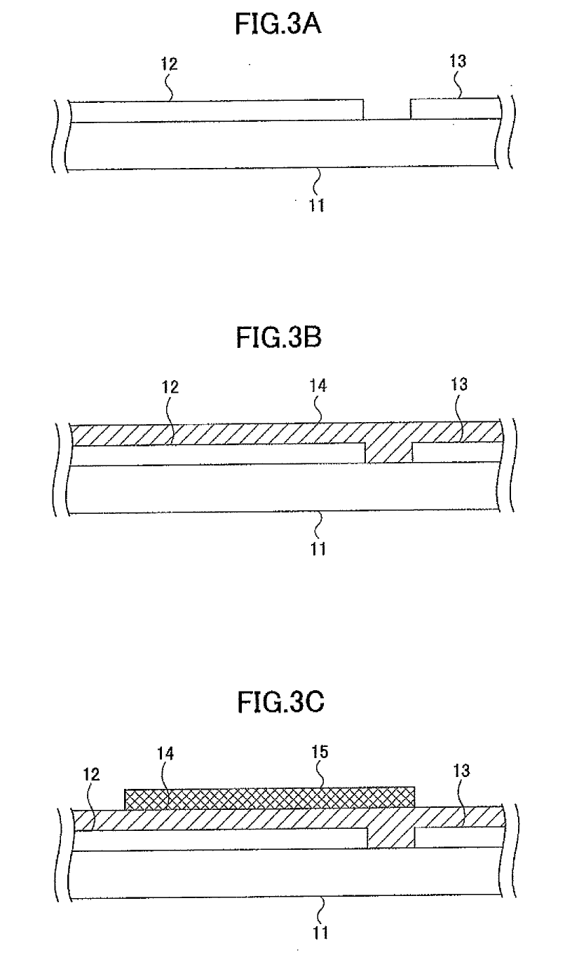

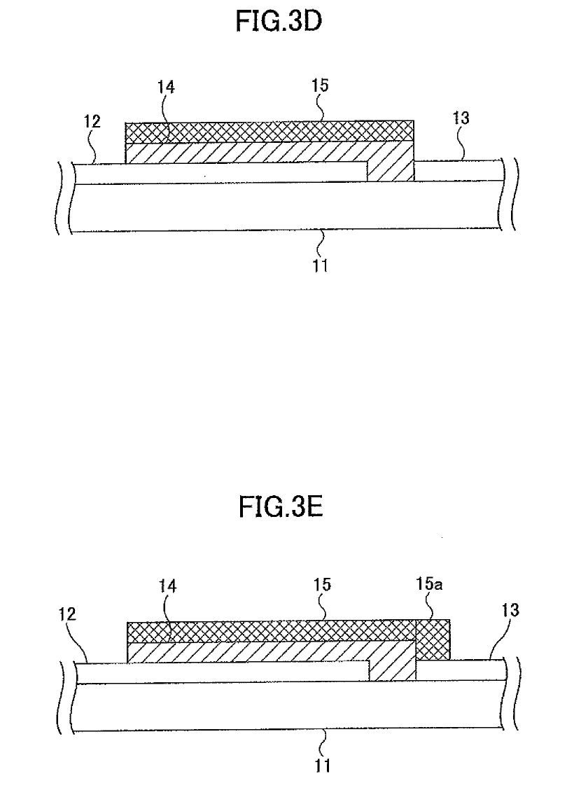

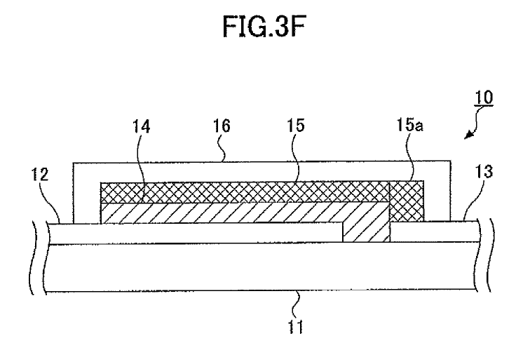

Next, in the processing chamber SP2, a draw-out negative electrode is patterned by mask-sputtering. Next, in the processing chamber CVD1, an insulating protective film made of an inorganic material, such as silicon nitride (SiN), is formed by CVD technique in a manner so as to cover the organic layer. The above-described substrate processing steps are described below with reference to FIGS. 3A through BF.

Herewith, a light emitting device having, on the in-process substrate W, the organic layer sandwiched between the positive and negative electrodes can be formed. This light emitting device is sometimes called an organic EL device.

In the manufacturing apparatus 100 according to the present embodiment, the in-process substrate W is hermetically contained in the substrate holding container B1 while being transferred between the processing chambers. As a result, the organic layer on the in-process substrate is isolated from the ambient atmosphere including much oxygen and water. Herewith, it is possible to effectively prevent the quality degradation of the light emitting device.

For example, in the case of a conventional cluster apparatus for manufacturing a light emitting device, an in-process substrate is generally bare and exposed while being transferred. In addition, multiple processing chambers are connected to each other in a substrate transfer chamber, the content inside of which is brought to a reduced pressure or replaced with an inert gas.

Accordingly, there are concerns that the organic layer (in-process substrate) may be exposed to the atmosphere due to failure or maintenance of the manufacturing apparatus, which could lead to quality degradation of the light emitting device. In addition, there are limitations in handling failure situations and maintenance of the manufacturing apparatuses due to the necessity of preventing the organic layer from being exposed to the atmosphere, thereby posing a problem for the improvement of the light emitting device production.

On the other hand, in the manufacturing apparatus according to one embodiment of the present invention, the in-process substrate W on which an organic layer is formed is transferred while protected (hermetically contained) in the substrate holding container B1, and the substrate holding container B1 is sequentially connected to the substrate transfer chambers T1-T6. Accordingly, there is less concern that the organic layer may be exposed to the ambient atmosphere, and it is possible to manufacture high-quality light emitting device with good productivity. The atmosphere inside the substrate holding container B1 is preferably brought to a reduced pressure or replaced with a predetermined fill gas (specifically, air being replaced with the fill gas), as explained above.

Since the in-process substrate W on which the organic layer is formed is transferred while hermetically contained in the substrate holding container P1, maintenance and failure repairs of the processing chambers CL1, EL1, SP1, ET1, SP2 and CVD1 can be handled readily, which results in an improvement in the productivity of the manufacturing apparatus 100. Furthermore, as for the substrate transfer chambers T1-T6 also, maintenance and failure repairs can be made easily.

Since there is a smaller risk of the in-process substrate W being exposed to the atmosphere, flexibility in the structures, transfer path and maintenance methods of the processing chambers CL1, EL1, SP1, ET1, SP2 and CVD1 dramatically improves, resulting in an improvement in the productivity of the manufacturing apparatus 100.

With reference to FIGS. 3A through 3F, the following gives a detailed description of a method for manufacturing a light emitting device using the above-described manufacturing apparatus 100. Note that the same reference numerals are given to components that have been described above, and their explanations may be omitted therein.

First, a step illustrated in FIG. 3A corresponds to the substrate processing step performed in the processing chamber CL1. In this step, cleaning is carried out on a so-called electrode-formed substrate (corresponding to the in-process substrate W) configured by forming a positive electrode 12 made of a transparent material, such as ITO, and a draw-out negative electrode 13 on a transparent substrate 11 made of, for example, glass. Note that the positive electrode 12 (and the draw-out electrode 13) is formed by, for example, sputtering.

A control device, such as a TFT (thin film transistor), for controlling emission of the light emitting device may be embedded in the substrate 11. In applying the light emitting device of the present embodiment to a display device, for example, it is often the case that a control device, such as a TFT, is embedded for each pixel.

In this case, the source electrode of each TFT is connected to the positive electrode 12, the gate and drain electrodes of the TFT are connected to gate and drain lines, respectively, having a lattice configuration, and display control is performed with respect to each pixel. The draw-out electrode 13 is connected to a predetermined control circuit (not shown). A drive circuit of such a display device is called an active matrix drive circuit. Note that FIG. 3A omits a graphical representation of such an active matrix drive circuit.

Next, in the substrate processing step of FIG. 3B performed in the processing chamber EL1, an organic layer 14 including an emitting layer (organic EL layer) is formed by vapor deposition in a manner to cover the positive electrode 12, the draw-out electrode 13 and exposed parts of the substrate 11. A mask is not used in the vapor deposition, and the organic layer 14 is formed over substantially the entire surface of the substrate 11.

Next, in the substrate processing step of FIG. 3C performed in the processing chamber SP1, a negative electrode 15 made of, for example, Ag (silver) is patterned, on the organic layer 14, into a predetermined shape by, for example, sputtering using a pattern mask. Alternatively, the negative electrode 15 may first be formed over the entire surface of the organic layer 14, and then patterned by photolithographic etching.

Next, in the substrate processing step of FIG. 3D performed in the processing chamber ET1, the organic layer 14 is patterned by, for example, plasma etching while using the patterned negative electrode 15 formed in the step of FIG. 3C as an etching mask. This etching process removes parts of the organic layer 14 which have to be stripped (for example, parts of the organic layer 14 over the draw-out electrode 13 and regions where the emitting layer is unnecessary) to form a pattern of the organic layer 14.

In the above case, the patterning of the organic layer 14 does not have to be achieved by mask vapor deposition, unlike the conventional method. Therefore, it is possible to avoid various problems associated with mask vapor deposition. For example, it is possible to prevent a reduction in the patterning accuracy of the vapor-deposited layer (i.e. organic layer 14) attributable to deformation of the mask due to an increase in the mask temperature during vapor deposition.

Next, in the substrate processing step of FIG. 3E performed in the processing chamber SP2, a connection line 15a for electrically connecting the negative electrode 15 and the draw-out electrode 13 is patterned by, for example, sputtering using a patterned mask.

Next, in the substrate processing step of FIG. 3F performed in the processing chamber CVD1, an insulating protective film 16 made of, for example, silicon nitride (SiN), is formed on the substrate 11 by a CVD technique using a patterned mask in a manner to cover a part of the positive electrode 12, a part of the draw-out electrode 13, the organic layer 14, the negative electrode 15 and the connection line 15a.

Herewith, a light emitting device 10 is formed in which the organic layer 14 sandwiched between the positive electrode 12 and the negative electrode 15 is formed on the substrate 11. The light emitting device 10 is sometimes called an organic EL device.

The light emitting device 10 is designed to emit light when a voltage is applied between the positive electrode 12 and the negative electrode 15. With the voltage application, holes and electrons are injected into an emitting layer included in the organic layer 14 from the positive electrode 12 and the negative electrode 15, respectively, and then recombine to emit light.

The emitting layer can be made of, for example, polycyclic aromatic hydrocarbon, a hetero aromatic compound, or an organometallic complex compound. Using such a material, the emitting layer may be formed by, for example, vapor deposition.

In order to improve the luminous efficiency of the emitting layer, a hole transport layer and a hole injection layer, for example, may be formed in the organic layer 14 between the emitting layer and the positive electrode 12. One or both of the hole transport layer and the hole injection layer may be omitted.

Similarly, in order to improve the luminous efficiency of the emitting layer, an electron transport layer and an electron injection layer, for example, may be formed in the organic layer 14 between the emitting layer and the negative electrode 15. One or both of the electron transport layer and the electron injection layer may be omitted.

At the interface between the organic layer 14 and the negative electrode 15, a layer may be provided to which a material for adjusting the work function of the interface (for improving the luminous efficiency), such as Li, LiF, or CsCO₃, is added.

The emitting layer may be formed, for example, using an aluminoquinolinol complex (Alq3) as a host material and rubrene as a doping material; however, the emitting layer is not limited to these materials, and can be formed using various other materials.

The thickness of the positive electrode 12 is in the range of 100 μm to 200 μm; the thickness of the organic layer 13, 50 μm to 200 μm; and the thickness of the negative electrode 14, 50 μm to 300 μm.

The light emitting device 10 is applicable to, for example, display devices (organic EL display devices) and surface emitting devices (lightings and light sources); however, the use of the light emitting device 10 is not limited to these, and the light emitting device 10 is applicable to various other electronic devices.

The following describes, with reference to the drawings, structural examples of the processing chambers used in the manufacturing apparatus 100. Note that the same reference numerals are given to components that have been described above, and their explanations may be omitted herein.

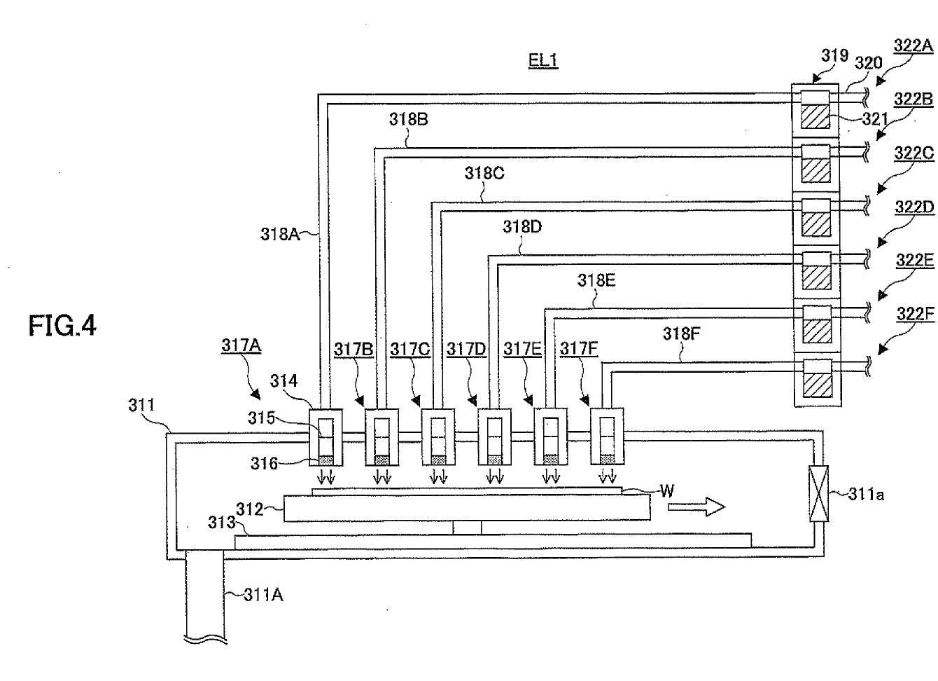

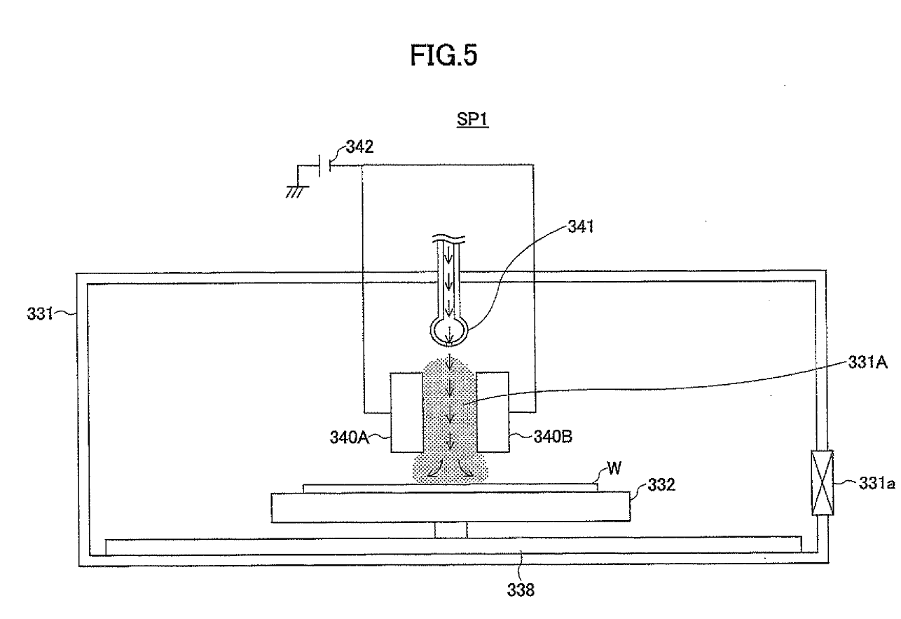

FIG. 4 is a schematic diagram of the processing chamber (layer formation chamber) EL1 of the lights emitting-device manufacturing apparatus 100. In the processing chamber EL1, the substrate processing step of FIG. 3B is performed to form the organic layer 14 by vapor deposition.

With reference to FIG. 4, the layer formation chamber EL1 includes a processing container 311 in which a mounting platform 312 for holding the in-process substrate W (corresponding to the substrate 11 of FIG. 3A) is provided. The atmosphere inside the processing container 311 is exhausted through an exhaust line 311A to which a vacuum pump (not shown) is connected, in order to create reduced pressure.

Outside the processing container 311, a layer-formation-material-gas generating unit 322A is disposed. The layer-formation-material-gas generating unit 322A generates a layer-formation material gas (gas material) by, for example, evaporating or sublimating a vapor deposition material 321 in solid or liquid form.

The layer-formation-material-gas generating unit 322A includes a material container 319 and a carrier gas supply line 320. The layer formation material 321 stored in the material container 319 is heated by, for example, a heater (not shown), thereby generating the layer formation material gas (gas material). The generated layer formation material gas is transported through a transport line 318A together with a carrier gas supplied from the carrier gas supply line 320, and then supplied to a layer-formation-material-gas supply unit 317A provided in the processing container 311. Then, the layer-formation-material-gas supply unit 317A supplies the layer-formation material gas to the vicinity of the in-process substrate W in the processing container 311 so as to form a layer (by vapor deposition) on the in-process substrate W.

That is, according to the above structure, the organic layer 14 can be formed in a face-up configuration. In forming a layer by vapor deposition using a conventional light-emitting-device manufacturing apparatus, it is necessary to perform a layer formation in a face-down configuration, where a surface of the in-process substrate on which a layer is formed faces downward, because a material evaporated or sublimated from a vapor deposition source in the processing container is deposited on the in-process substrate. Accordingly, the conventional light-emitting-device manufacturing apparatus leaves the problem that, if the in-process substrate is large, handling becomes difficult, leading to a reduction in the light emitting device production.

On the other hand, the above processing chamber EL1 allows the layer formation in a face-up configuration, and therefore, a large in-process substrate can be readily handled. As a result, the light emitting device production improves and the production cost can be therefore reduced.

The layer-formation-material-gas supply unit 317A includes, for example, a cylindrical or box-shaped supply-unit body 314 to which the transport line 318A is connected. Inside the supply-unit body 314, a flow guide 315 is provided for controlling the flow of the layer-formation material gas. In addition, a filter plate 316 made of, for example, a porous metal material (metal filter) is provided on the supply-unit body 314, at the end facing the in-process substrate W.

On the processing container 311, layer-formation-material-gas supply units 317B-317F, each having the same structure as that of the layer-formation-material-gas supply unit 317A, are aligned in a straight line with the layer-formation-material-gas supply unit 317A. The layer-formation-material-gas supply units 317B-317F are connected to layer-formation-material-gas generating units 322B-322F, respectively, via transport lines 318B-318F, respectively. Each of the layer-formation-material-gas generating units 322B-322F has the same structure as that of the layer-formation-material-gas generating unit 322A.

The mounting platform 312 is designed to be movable in a manner to correspond to multiple supplies of the layer-formation material gas from the layer-formation-material-gas supply units 317A-317F. For example, the mounting platform 312 is designed to be movable on a transport rail 313 provided at the bottom of the processing container 311 in a manner to travel parallel to the alignment of the layer-formation-material-gas supply units 317A-317F.

The mounting platform 312 is moved in accordance with the multiple supplies of the layer-formation material gas from the layer-formation-material-gas supply units 317A-317F, whereby the organic layer can be formed on the in-process substrate W in a face-up configuration to have a multiple layer structure.

A gate valve 311a is provided on the processing container 311, at the end connected to the substrate transfer chamber T2. By opening the gate valve 311a, the in-process substrate W can be carried into/out from the processing container 311.

FIG. 5 is a schematic diagram of the processing chamber (layer formation chamber) SP1 of the light-emitting-device manufacturing apparatus 100. In the processing chamber SP1, the substrate processing step of FIG. 3C is performed to form the negative electrode layer 15 by sputtering. Note that the processing chamber SP2 has the same structure as that of the processing chamber SP1.

With reference to FIG. 5, the layer formation chamber SP1 includes a processing container 331 in which a mounting platform 332 for holding the in-process substrate W is provided. The atmosphere inside the processing container 311 is exhausted through an exhaust line (not shown) to which a vacuum pump is connected, to create reduced pressure. The mounting platform 332 is designed to be movable parallel to and on a transport rail 338 provided at the bottom of the processing container 311.

A gate valve 331a is provided on the processing container 331, at the end connected to the substrate transfer chamber T3. By opening the gate valve 331a, the in-process substrate W can be carried into/oft from the processing container 331.

In the processing container 331, targets 340A and 340B to each of which a voltage is applied oppose each other. Each of the two targets 340A and 340B disposed above the substrate mounting platform 332 has a structure elongated in a direction perpendicular to the direction in which the substrate mounting platform 332 travels.

In the processing container 331, a gas supply unit 341 for supplying a process gas made of, for example, Ar (argon) and used in sputtering is provided in a space 331A between the targets 340A and 340B. The process gas is plasma-excited when voltages are applied to the targets 340A and 340B from a power source 342.

When electric power is applied to the targets 340A and 340B from the power source 342, the plasma is excited in the space 331A and the targets 340A and 340B are sputtered, whereby a layer is formed on the in-process substrate W.

The processing chamber SP1 is characterized in that the in-process substrate W is positioned away from the space in which the plasma is excited (space 331A), and therefore, the organic layer 14, which is an object of the layer formation, is less likely to receive damage caused by ultraviolet light associated with the plasma excitation and collision processes between sputtered particles. Accordingly, the processing chamber SP1A allows a reduction in the damage to the organic layer 14 in the formation of the negative electrode (Ag or Al) 15.

The device for forming the negative electrode layer is not limited to the above-described processing chamber SP1, and a sputtering device having a normal target structure may be used.

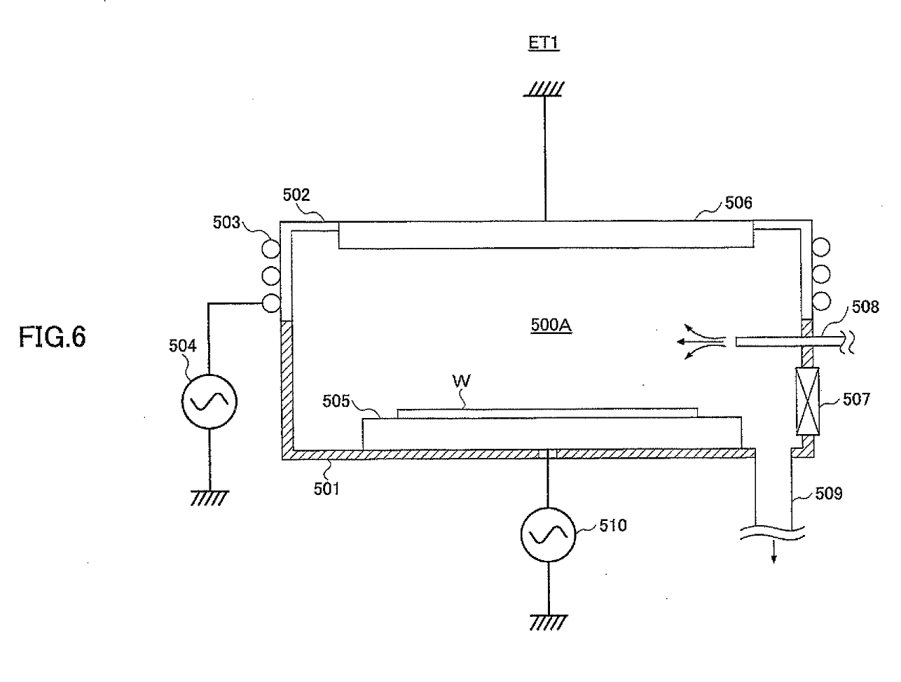

FIG. 6 is a schematic diagram of the processing chamber (etching processing chamber) ET1 of the light-emitting-device manufacturing apparatus 100. In the processing chamber ET1, the substrate processing step of FIG. 3D is performed to pattern the organic layer 14 by etching.

With reference to FIG. 6, the processing chamber ET1 includes processing containers 501 and 502 defining an internal space 500A when the processing containers are fit together. In the internal space 500A, an earth plate 506 and a substrate mounting platform 505 oppose each other. The internal space 500A is exhausted through an exhaust line 509 to which an exhaust unit (not shown), such as an exhaust pump, is connected, to create reduced pressure.

The processing container 501 is made of, for example, metal and the processing container 502 is made of a dielectric substance. Outside the processing container 502, coils 503, to which high-frequency power is applied from a high-frequency power source 504, are provided. In addition, high-frequency power is applied to the substrate mounting platform 505 from a high-frequency power source 510.

To the internal space 500A, a process gas made of, for example, N₂/Ar and used in etching is supplied by a gas supply unit 508. The process gas is plasma-excited when high-frequency power is applied to the coils 503. Such a plasma is sometimes called a dense plasma (for example, ICP (inductive coupled plasma)). Using the process gas dissociated by the dense plasma, the substrate processing step of FIG. 3D (i.e. etching on the organic layer 14 using the negative electrode 15 as a mask) can be performed.

A gate valve 507 is provided on the processing container 501, at the end connected to the substrate transfer chamber T4. By opening the gate valve 507, the in-process substrate W can be carried into/out from the processing container 501.

In the case where the negative electrode 15 includes Ag, nitrogen (N₂) is preferably used as the process gas. Compared to oxygen and hydrogen, for example, nitrogen has a less corrosive effect on metals, such as Ag, and allows efficient etching of the organic layer 14.

The plasma that dissociates the process gas is preferably a so-called dense plasma which dissociates nitrogen with high efficiency; however, the dense plasma is not limited to ICP, and the same effect can be achieved by using a microwave plasma.

The organic layer may be patterned by etching using, for example, a planar type plasma (for example, RIE).

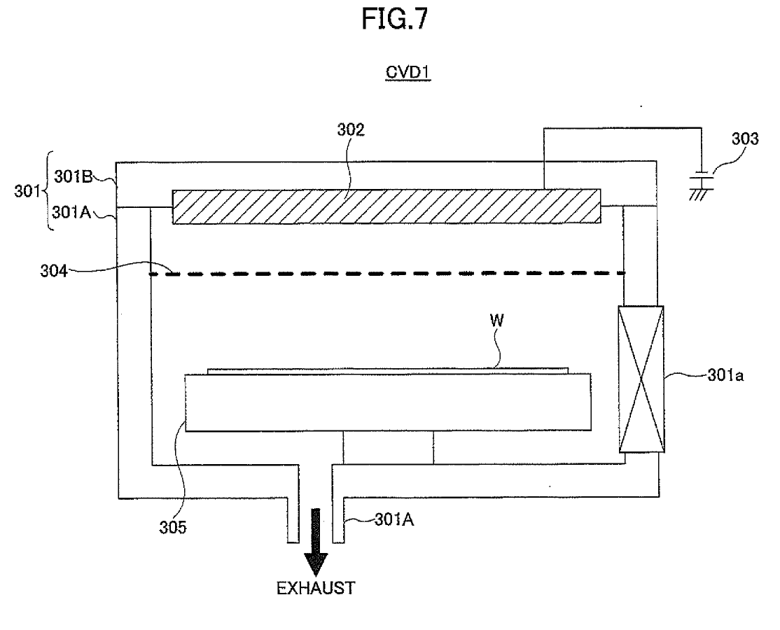

FIG. 7 is a schematic diagram of the processing chamber (CVD layer formation chamber) CVD1 of the light-emitting-device manufacturing apparatus 100. In the processing chamber CVD1, the substrate processing step of FIG. 3F is performed to form the protective layer 16.

With reference to FIG. 7, the processing chamber CVD1 includes a processing container 301 in which a mounting platform 305 for holding the in-process substrate W is provided. The atmosphere inside the processing container 301 is exhausted through an exhaust line 301A to which a vacuum pump (not shown) is connected, to create reduced pressure. The processing container 301 has a structure in which a lid part 301B is provided at an opening disposed at one end of a lower container 301A in, for example, a substantially cylindrical shape. In the lid part 301B, an antenna 302 in, for example, a substantially disk shape is provided, and microwaves are applied to the antenna 302 from a power source 303.

A gas supply unit 304 for supplying a layer-formation material gas to the processing container CVD1 is provided between the antenna 302 and the mounting platform 305. The gas supply unit 304 has, for example, a lattice structure in which microwaves pass through holes provided on the lattice.

Accordingly, the layer-formation material gas supplied by the gas supply unit 304 is plasma-excited by the microwaves from the antenna 302, whereby the protective layer (SiN layer) 16 is formed on the in-process substrate held on the mounting platform 305.

A gate valve 301a is provided on the processing container 301, at the end connected to the substrate transfer chamber T6. By opening the gate valve 301a, the in-process substrate W can be carried into/out from the processing container CVD1.

The above-described structures of the processing chambers EL1, SP1, ET1 and CVD1 are merely examples to which the present invention is not limited.

The structures, layouts and number of the processing chambers can be changed or modified in various ways. For example, if a substrate processing step takes a long time to complete, two or more processing chambers may be provided for the substrate processing step in order to improve the efficiency of the substrate processing step. In addition, for each substrate processing step, multiple processing chambers may be provided as backup used during maintenance.

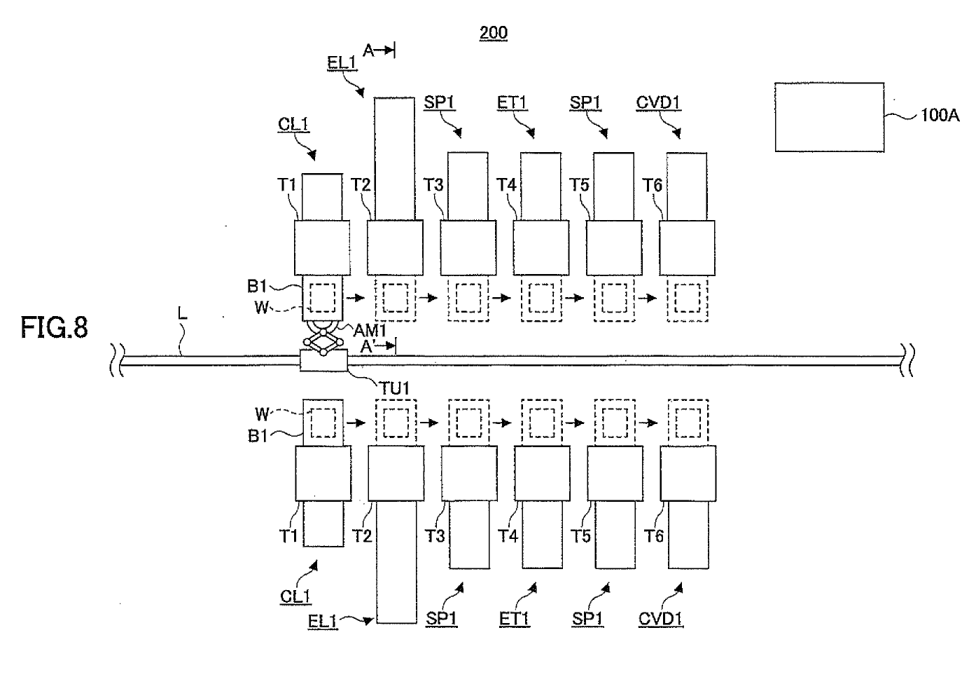

FIG. 8 shows a light-emitting-device manufacturing apparatus 200, which is a modification of the light-emitting-device manufacturing apparatus 100 of FIG. 1. Note that the same reference numerals are given to components that have been described above, and their explanations are omitted below. In addition, components to which no particular descriptions are provided should be regarded the same as corresponding parts of the manufacturing apparatus 100 of FIG. 1. Note that FIG. 8 omits the holding container stations BA1 and BA2 illustrated in FIG. 1.

With reference to FIG. 8, the manufacturing apparatus 200 includes two each of the processing chambers CL1, EL1, SP1, ET1, SP2 and CVD1. In accordance with these processing chambers, the number of the substrate transfer chambers T1-T6 is also increased.

The two processing chambers of each kind CL1, EL1, SP1, ET1, SP2 and CVD1 are arranged to oppose each other across the transfer rail L. In this case, the holding-container transfer unit TU1 connects the substrate holding container B1 to one of the two opposing processing containers.

The above structure achieves favorable manufacturing efficiency of the manufacturing apparatus 200 and favorable efficiency in maintenance and repair works since multiple processing chambers are provided for each kind of processing chambers. Because two each of the processing chambers CL1, EL1, SP1, ET1, SP2 and CVD1 are provided, the manufacture of the light emitting devices can be continued even if one of the processing chambers CL1, EL1, SP1, ET1, SP2 and CVD1 malfunctions.

Even if a processing chamber or a substrate transfer chamber is stopped and opened for maintenance or repair work, the remaining processing chambers and substrate transfer chambers are virtually not affected since the respective processing chambers and substrate transfer chambers are isolated from each other.

Herewith, the risk of the organic layer of the light emitting device being exposed to oxygen and water in the atmosphere is reduced, and it is possible to manufacture high-quality light emitting devices with good productivity.

As has been described above, one embodiment of the present invention is able to provide a light-emitting-device manufacturing apparatus for manufacturing a light emitting device by forming, on an in-process substrate, an organic layer including an emitting layer. The light-emitting-device manufacturing apparatus includes multiple processing chambers to which the in-process substrate is sequentially transferred to be subjected to multiple substrate processing steps; and multiple substrate transfer chambers, each of which is connected to a different one of the processing chambers. A substrate holding container configured to contain the in-process substrate is sequentially connected to the substrate transfer chambers in order that the in-process substrate is sequentially transferred to the processing chambers to be subjected to the substrate processing steps.

The substrate holding container may be capable of hermetically containing the in-process substrate. A vacuum may be produced in the substrate holding container while the substrate holding container is connected to one of the substrate transfer chambers. The substrate holding container may be filled with a predetermined fill gas while connected to one of the substrate transfer chambers. A thrust pin for supporting the in-process substrate may be provided in the substrate holding container. The processing chambers may include an organic layer forming chamber in which the organic layer is formed and an electrode forming chamber in which an electrode used to apply a voltage to the organic layer is formed. In the organic layer forming chamber, the organic layer may be formed in a manner to have a multilayer structure, layers of which are continuously formed by vapor deposition and which include the emitting layer that emits light by voltage application. In the electrode forming chamber, the electrode may be formed by sputtering using two targets that oppose each other. The processing chambers may include an etching chamber in which the organic layer is patterned by etching.

Also, another embodiment of the present invention is able to provide a light-emitting-device manufacturing method for manufacturing a light emitting device by performing multiple substrate processing steps in multiple processing chambers to form, on an in-process substrate, an organic layer including an emitting layer. A substrate holding container which contains the in-process substrate is sequentially connected to multiple substrate transfer chambers, each of which is connected to a different one of the processing chambers, in order that the in-process substrate is sequentially transferred to the process chambers to be subjected to the substrate processing steps.

The substrate holding container may be transferred while hermetically containing the in-process substrate, and sequentially connected to the substrate transfer chambers. A vacuum may be produced in the substrate holding container while the substrate holding container is connected to one of the substrate transfer chambers. The substrate holding container may be filled with a predetermined fill gas while connected to one of the substrate transfer chambers. The substrate processing steps may include an organic layer forming step for forming the organic layer and an electrode forming step for forming an electrode used to apply a voltage to the organic layer. In the organic layer forming step, the organic layer may be formed in a manner to have a multilayer structure, the layers of which are continuously formed by vapor deposition and include the emitting layer that emits light by voltage application. In the electrode forming step, the electrode may be formed by sputtering using two targets that oppose each other. The substrate processing steps may include an etching step for patterning the organic layer by etching.

Thus, the present invention has been described with reference to preferred embodiments. While the present invention has been shown and described with particular examples, it should be understood that the present invention is not limited to the particular examples, and that various changes and modification may be made to the particular examples without departing from the scope of the appended claims.

This application is based upon and claims the benefit of priority of Japanese Patent Application 2006-158724, filed on Jun. 7, 2006, the entire contents of which are hereby incorporated herein by reference.

### INDUSTRIAL APPLICABILITY

The present invention is capable of providing an apparatus and method for manufacturing a light emitting device with good productivity.

1. A light-emitting-device manufacturing apparatus for manufacturing a light emitting device by forming, on an in-process substrate, an organic layer including an emitting layer, the light-emitting-device manufacturing apparatus comprising:
a plurality of processing chambers to which the in-process substrate is sequentially transferred to be subjected to a plurality of substrate processing steps; and
a plurality of substrate transfer chambers, each of which is connected to a different one of the processing chambers;
wherein a substrate holding container configured to contain the in-process substrate therein is sequentially connected to the substrate transfer chambers in order that the in-process substrate is sequentially transferred to the processing chambers to be subjected to the substrate processing steps.

2. The light-emitting-device manufacturing apparatus as claimed in claim 1, wherein the substrate holding container is capable of hermetically containing the in-process substrate.

3. The light-emitting-device manufacturing apparatus as claimed in claim 1, wherein a vacuum is produced in the substrate holding container while the substrate holding container is connected to one of the substrate transfer chambers.

4. The light-emitting-device manufacturing apparatus as claimed in claim 1, wherein the substrate holding container is filled with a predetermined fill gas while connected to one of the substrate transfer chambers.

5. The light-emitting-device manufacturing apparatus as claimed in claim 1, wherein a thrust pin for supporting the in-process substrate is provided in the substrate holding container.

6. The light-emitting-device manufacturing apparatus as claimed in claim 1, wherein the processing chambers include an organic layer forming chamber in which the organic layer is formed and an electrode forming chamber in which an electrode used to apply a voltage to the organic layer is formed.

7. The light-emitting-device manufacturing apparatus as claimed in claim 6, wherein in the organic layer forming chamber, the organic layer is formed in a manner to have a multilayer structure, layers of which are continuously formed by vapor deposition and include the emitting layer that emits light by voltage application.

8. The light-emitting-device manufacturing apparatus as claimed in claim 6, wherein in the electrode forming chamber; the electrode is formed by sputtering using two targets that oppose each other.

9. The light-emitting-device manufacturing apparatus as claimed in claim 6, wherein the processing chambers include an etching chamber in which the organic layer is patterned by etching.

10. A light-emitting-device manufacturing method for manufacturing a light emitting device by performing a plurality of substrate processing steps in a plurality of processing chambers to thereby form, on an in-process substrate, an organic layer including an emitting layer,
wherein a substrate holding container which contains the in-process substrate therein is sequentially connected to a plurality of substrate transfer chambers, each of which is connected to a different one of the processing chambers, in order that the in-process substrate is sequentially transferred to the processing chambers to be subjected to the substrate processing steps.

11. The light-emitting-device manufacturing method as claimed in claim 10, wherein the substrate holding container is transferred while hermetically containing the in-process substrate therein, and sequentially connected to the substrate transfer chambers.

12. The light-emitting-device manufacturing method as claimed in claim 10, wherein a vacuum is produced in the substrate holding container while the substrate holding container is connected to one of the substrate transfer chambers.

13. The light-emitting-device manufacturing method as claimed in claim 10, wherein the substrate holding container is filled with a predetermined fill gas while connected to one of the substrate transfer chambers.

14. The light-emitting-device manufacturing method as claimed in claim 10, wherein the substrate processing steps include an organic layer forming step for forming the organic layer and an electrode forming step for forming an electrode used to apply a voltage to the organic layer.

15. The light-emitting-device manufacturing method as claimed in claim 14, wherein in the organic layer forming step, the organic layer is formed in a manner to have a multilayer structure, layers of which are continuously formed by vapor deposition and include the emitting layer that emits light by voltage application.

16. The light-emitting-device manufacturing method as claimed in claim 14, wherein in the electrode forming step, the electrode is formed by sputtering using two targets that oppose each other.

17. The light-emitting-device manufacturing method as claimed in claim 14, wherein the substrate processing steps include an etching step for patterning the organic layer by etching.
